(19) United States
(12) Patent Application Publication
(10) Pub. No.: US 2020/0411708 A1
(43) Pub. Date: Dec. 31, 2020

(54) SOLAR CELL DESIGN OPTIMIZED FOR PERFORMANCE AT HIGH RADIATION DOSES

(71) Applicant: The Boeing Company, Chicago, IL (US)

(72) Inventors: Philip T. Chiu, La Crescenta, CA (US); Christopher M. Fetzer, Saugus, CA (US)

(73) Assignee: The Boeing Company, Chicago, IL (US)

(21) Appl. No.: 16/452,083

(22) Filed: Jun. 25, 2019

(51) Int. Cl. H01L 31/041; H01L 31/056; H01L 31/0687; H01L 31/18; H01L 31/0693

(52) U.S. Cl. CPC H01L 31/041; H01L 31/056; H01L 31/0693; H01L 31/1844; H01L 31/0687

(57) ABSTRACT

A solar cell optimized for performance at high radiation doses, wherein the solar cell includes: a sub-cell comprised of a base and an emitter; the base of the sub-cell has a thickness of about 2 to 3 μm; the base of the sub-cell is doped at about 1e14 cm⁻³ to 1e16 cm⁻³; and a reflector is inserted behind the sub-cell to maximize current generated by the sub-cell.

### STATEMENT REGARDING FEDERALLY SPONSORED RESEARCH AND DEVELOPMENT

This invention was made with Government support under FA9453-14-C-0372 awarded by the Department of Defense. The government has certain rights in this invention.

### BACKGROUND

### 1. Field

The disclosure is related generally to a solar cell design optimized for performance at high radiation doses.

### 2. Background

Until recently, space satellites operated in geosynchronous (GEO) orbits with total effective radiation dose of about 1e15 e-/cm². Over the past few years, missions have diversified to include those middle earth orbits (MEO) with far higher effective radiation doses that are an order of magnitude higher than that of GEO. Therefore, solar cell performance in high radiation space environments is becoming increasingly critical.

There have been previous methods to solve this problem. One such method is described in U.S. Pat. No. 9,252,313, issued Feb. 2, 2016, to Matthias Meusel et al., entitled “Monolithic Multiple Solar Cells,” and assigned to Azur Space Solar Power GmbH (hereinafter referred to as the '313 patent).

The '313 patent specifies the use of a semiconductor mirror disposed between two partial cells, with the thickness of the partial cell above the mirror cut in half by using the mirror, without drastically reducing the absorption of the partial cell. However, the design of the '313 patent falls off in performance quickly after high radiation doses of about 1e15 e-/cm² or greater.

Thus, there is a need for solar cell designs optimized for performance at high radiation doses.

### SUMMARY

To overcome the limitations described above, and to overcome other limitations that will become apparent upon reading and understanding the present specification, the present disclosure describes a device, a method of fabricating the device, and a method of generating a current using the device, wherein the device is a solar cell optimized for performance at high radiation doses, and the solar cell includes: a sub-cell comprised of a base and an emitter; the base of the sub-cell has a thickness of about 2 to 3 μm; the base of the sub-cell is doped at about 1e14 cm⁻³ to 1e16 cm⁻³; and a reflector is inserted behind the sub-cell to maximize current generated by the sub-cell.

### DRAWINGS

Referring now to the drawings in which like reference numbers represent corresponding parts throughout:

FIGS. 1A and 1B are layer schematics of triple junction solar cells, wherein FIG. 1A is a baseline solar cell and FIG. 1B is a new solar cell.

FIG. 2 is a graph of internal quantum efficiency (IQE) vs. Wavelength (nm) for the baseline and new solar cells.

FIG. 3 shows four experimental splits for a comparison of LIV (light-current-voltage) data, including Voc (open current voltage), Jsc (short circuit current), Eff (solar cell efficiency at a maximum power point), and FF (fill factor) between the baseline and new solar cells.

FIG. 4 is a graph of power retention (NPmp) vs. 1 MeV e-dose (e-/cm2) (electron fluence) for the baseline and new solar cells.

FIG. 5 is a graph of end-of-life (EOL) efficiency (%) vs. 1 MeV e-dose (e-/cm2) (electron fluence) for the baseline and new solar cells.

FIG. 6A illustrates a method of fabricating a solar cell, solar cell panel and/or satellite.

FIG. 6B illustrates a resulting satellite having a solar cell panel comprised of solar cells.

FIG. 7 is an illustration of the solar cell panel in the form of a functional block diagram.

### DETAILED DESCRIPTION

In the following description, reference is made to the accompanying drawings which form a part hereof, and in which is shown by way of illustration a specific example in which the disclosure may be practiced. It is to be understood that other examples may be utilized and structural changes may be made without departing from the scope of the present disclosure.

Overview

The power retention of a standard triple junction (3J) space solar cell following exposure to space radiation is most greatly affected by the retention of the GaAs middle cell (i.e., middle sub-cell). This disclosure significantly improves on the power retention of the middle sub-cell by reducing the thickness of the base of the middle sub-cell to less than that required to fully absorb light and lowering the doping of the base of the middle sub-cell.

Preferably, the base of the middle sub-cell has a thickness of about 2 to 3 μm; more preferably the base of the middle sub-cell has a thickness of about 2.1 to 2.3 μm; and most preferably, the base of the middle sub-cell has a thickness of about 2.1 μm.

Preferably, the base of the middle sub-cell is p-type doped at about 1e14 cm⁻³ to 1e16 cm⁻³.

A reflector, such as a distributed Bragg reflector (DBR), is inserted behind the middle sub-cell to compensate for the reduced thickness of the middle sub-cell base and to maximize the current of the middle sub-cell. Preferably, the reflectance is centered at a wavelength of about 870 nm.

Experimentally, beginning-of-life (BOL) solar cell efficiencies at 32% have been demonstrated using this disclosure that are 4% relative better than the current industry standard. Moreover, the end-of-life (EOL) power of the solar cell at high electron fluences of about 1e15 e-/cm² to 1e16 e-/cm² using this disclosure exceeds the previous state-of-the-art solar cell by 12% relative.

Device

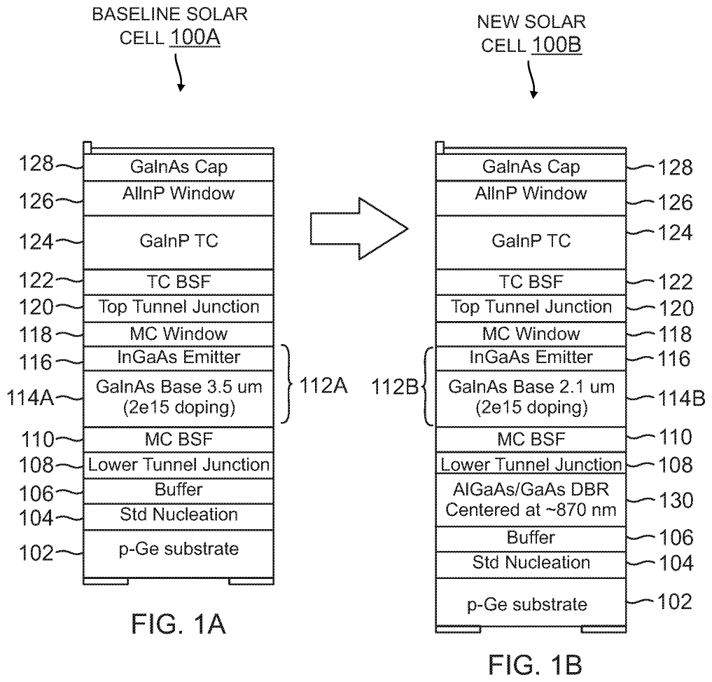

FIGS. 1A and 1B are layer schematics, each showing a cross-section of a device comprising baseline and new III-V 3J solar cells 100A, 100B, respectively, and describing both a method of fabricating the device and a method of generating a current using the device.

FIG. 1A shows the baseline III-V 3J solar cell 100A. The solar cell 100A includes a p-type doped germanium (p-Ge) substrate 102, upon which is deposited and/or fabricated a standard (std) nucleation layer 104, a buffer layer 106, a lower tunnel junction 108, a middle sub-cell (MC) back surface field (BSF) 110, a middle sub-cell 112A comprised of a base 114A and an emitter 116, wherein the base 114A is comprised of gallium indium arsenide (GaInAs) with p-type doping of about 1e14 cm⁻³ to 1e16 cm⁻³, and having a thickness of about 3.5 μm and the emitter 116 is comprised of indium gallium arsenide (InGaAs), an MC window 118, a top tunnel junction 120, a top sub-cell (TC) BSF 122, a top sub-cell 124 comprised of GaInP, a window 126 comprised of aluminum indium phosphide (AlInP), and a cap 128 comprised of GaInAs. The solar cell 100A may include other features not illustrated, such as an anti-reflection coating, and front and back metal contacts.

The baseline solar cell 100A has a fully-absorbing middle sub-cell 112A base 114A with a thickness of about 3.5 μm. The middle sub-cell 112A base 114A p-type doping is low at about 1e14 cm⁻³ to 1e16 cm⁻³, to increase the space charge region. The space charge region collects minority carriers regardless of reductions to the diffusion length of the middle sub-cell 112A caused by radiation damage. Such a layer design is optimized for radiation dose of about 1e15 e-/cm² or less.

FIG. 1B shows the new III-V 3J solar cell 100B according to this disclosure, wherein a reflector 130, i.e., a DBR 130 comprised of aluminum gallium arsenide (AlGaAs) and gallium arsenide (GaAs), is inserted behind the middle sub-cell 112B positioned between the buffer layer 106 and the lower tunnel junction 108, and the DBR 130 has a reflectance centered at a wavelength of about 870 nm. In addition, the middle sub-cell 112B includes a base 114B comprised of GaInAs with a p-type doping of about 1e14 cm⁻³ to 1e16 cm⁻³ that has a thickness of about 2.1 μm. Otherwise, the structure of 100B is the same as the structure of 100A.

The new solar cell 100B has two major changes from the baseline solar cell 100A, including a reduction in the middle sub-cell 112A base 114A of 3.5 μm to the middle sub-cell 112B base 114B thickness of 2.1 μm, and the addition of the DBR 130 with a center wavelength at 870 nm.

Experimental Results

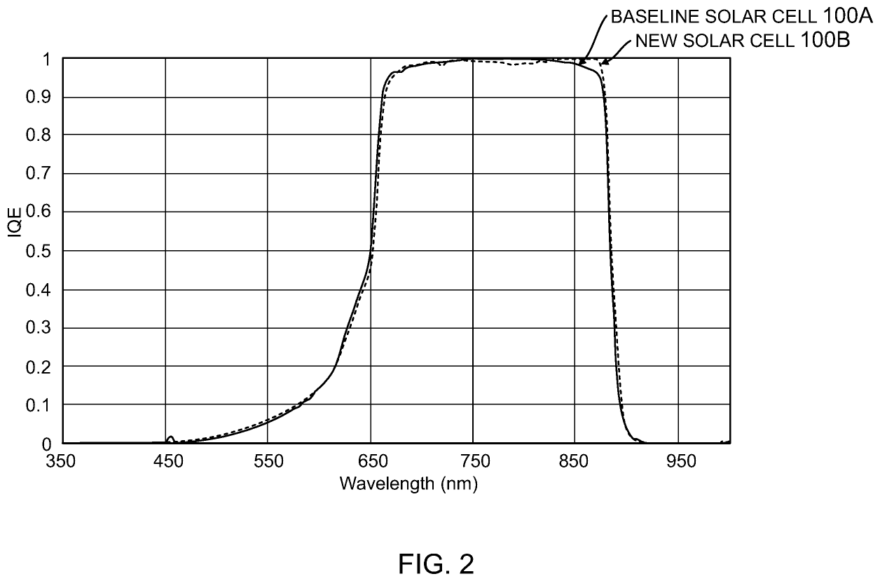

The use of the DBR 130 allows the middle sub-cell 112B base 114B to be thinned down to about 2.1 μm without compromising the current generated by the middle sub-cell 112B. This is demonstrated in FIG. 2, which is a graph that shows the internal quantum efficiency curves for the baseline solar cell 100A with a 3.5 μm thick middle sub-cell 112A base 114A, and the new solar cell 100B with a 2.1 μm thick middle sub-cell 112B base 114B.

Despite the fact that that the new solar cell 100B has a middle sub-cell 112B base 114B nearly half the thickness of the middle sub-cell 112A base 114A of the baseline solar cell 100A, the internal quantum efficiency (IQE) signatures are nearly identical and the integrated currents are the same within error. The thinner 2.1 μm middle sub-cell 112B base 114B for the new solar cell 100B also benefits the voltage of the new solar cell 100B. The thicker 3.5 μm middle sub-cell 112A base 114A has dark current near the back of the baseline solar cell 100A, where light intensities are low.

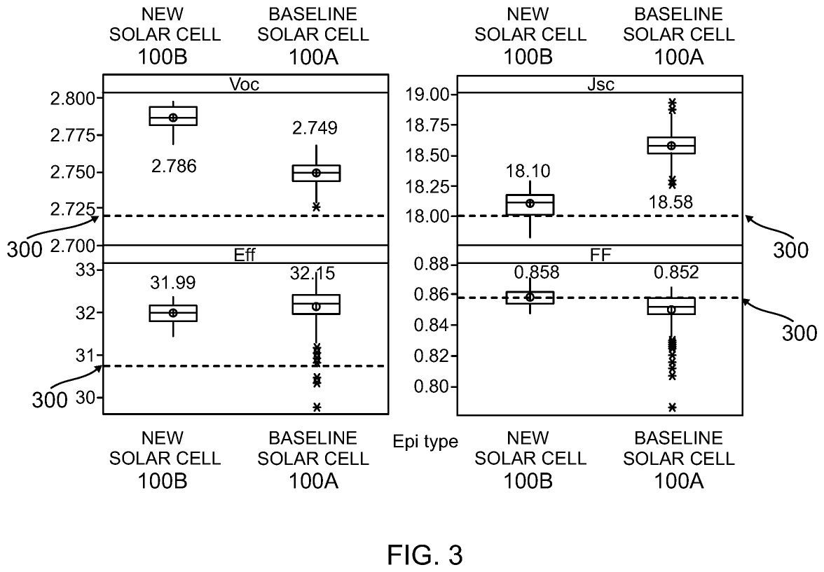

Partially as a consequence of the high middle sub-cell 112B current (from the DBR 130) and higher middle sub-cell 112B voltage (due to the middle sub-cell 112B base 114B being thinner), the new solar cell 100B has an exceptional BOL efficiency. The BOL LIV characteristics for the new solar cell 100B are summarized in FIG. 3.

FIG. 3 shows four experimental splits for a comparison of LIV (light-current-voltage) data, including Voc (open current voltage), Jsc (short circuit current), Eff (solar cell efficiency at a maximum power point), and FF (fill factor) between the baseline and new solar cells. The dotted lines 300 show the corresponding values for current state-of-the-art baseline solar cells 100A.

The new solar cell 100B is nearly 70 mV higher than the baseline solar cell 100A. The current of the new solar cell 100B matches that of the baseline solar cell 100A. Overall BOL efficiency for the new solar cell 100B is 4% higher than the baseline solar cell 100A.

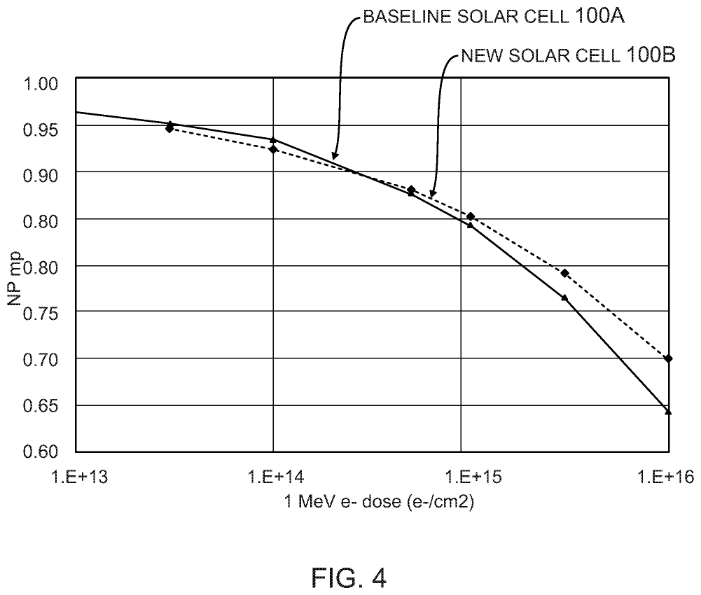

The low p-type doping (about 1e14 cm⁻³ to 1e16 cm⁻³) of the middle sub-cell 112B base 114B in the new solar cell 100B and the thinness (about 2.1 μm) of the middle sub-cell 112B base 114B in the new solar cell 100B has significant benefits in EOL performance, particularly at high radiation levels. A graph of power retention (NPmp) as a function of a 1 MeV electron radiation dose (e-dose) (e-/cm2) (electron fluence) for the baseline and new solar cells 100A, 100B is shown in FIG. 4. From FIG. 4, it is evident that the power retention of the new solar cell 100B is similar to the baseline solar cell 100A for the 1 MeV electron radiation dose from 0 to 5e14 e-/cm².

However, the 1 MeV electron radiation dose from about 1e15 e-/cm² to 1e16 e-/cm², the NPmp of the new solar cell 100B is clearly greater than the baseline solar cell 100A, with the difference increasing with increasing radiation dose. At the 1 MeV electron radiation doses of about 1e15 e-/cm² and 1e16 e-/cm², there is a 1% and 8% relative improvement in NPmp for the new solar cell 100B over the baseline solar cell 100A.

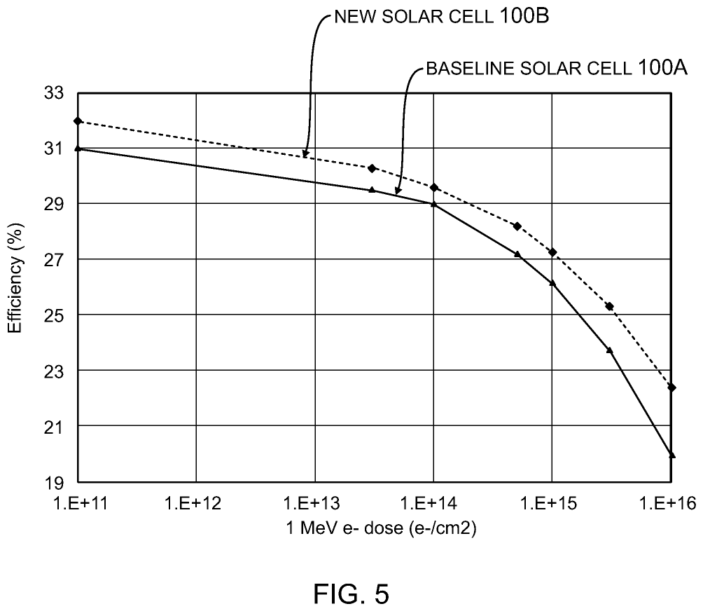

The combination of improved BOL efficiency and NPmp results in an improved EOL efficiency, where EOL efficiency=BOL efficiency×NPmp. A graph of EOL efficiency as a function of the 1 MeV electron radiation dose for the baseline and new solar cells 100A, 100B is shown FIG. 5.

From FIG. 5, it is clear that the EOL efficiency of the new solar cell 100B is greater than the baseline solar cell 100A at all radiation doses. At low doses, the difference in EOL efficiency is about 4%, due to the 4% advantage of the new solar cell 100B at BOL. Starting at the 1 MeV electron radiation dose of about 1e15 e-/cm², the difference in EOL efficiency starts to increase above about 4% due to the superior NPmp values for the new solar cell 100B relative to the baseline solar cell 100A. At the 1 MeV electron radiation dose of about 1e16 e-/cm², the difference in EOL efficiency is about 12%. This is a significant increase in EOL efficiency that is unmatched by other solar cells offered in the marketplace.

### SUMMARY

This disclosure, is the first known solution that combines low p-type doping of a thin middle sub-cell 112B base 114B with a DBR 130 to optimize middle sub-cell 112B retention in high radiation environments. This results in at least two advantages.

First, the use of a middle sub-cell 112B base 114B having a thickness of about 2 to 3 μm, more preferably about 2.1 to 2.3 μm, and most preferably about 2.1 μm, combined with an effective DBR 130, in the new solar cell 100B, results in an effective absorption length equal to a fully absorbing middle sub-cell 112A base 114A having a thickness of about 3 to 3.5 μm, without a DBR, in the baseline solar cell 100A. In this way, the BOL current of the middle sub-cell 112B in the new solar cell 100B, and hence the BOL efficiency of the new solar cell 100B, is not compromised to improve EOL efficiency. Consequently, the new solar cell 100B is still able to achieve BOL efficiency levels of near 32% that are 4% relative above the current state-of-the-art baseline solar cell 100A.

Second, the relatively thinner middle sub-cell 112B base 114B in the new solar cell 100B, combined with the low p-type doping of the middle sub-cell 112B base 114B in the new solar cell 100B, results in power retention with a radiation dose of about 1e15 e-/cm2 to 1e16 e-/cm2 that is unmatched in the industry. As a result, power retention and EOL power for the new solar cell 100B solution is 12% better than the current state-of-the-art baseline solar cell 100A at these radiation doses.

The result of this disclosure is a new solar cell 100B design optimized for performance at high radiation doses that exhibits an EOL efficiency 12% better than present state-of-the-art baseline solar cell 100A designs after a MEO-like radiation dose of about 1e16 e-/cm².

### Alternatives and Modifications

The description set forth above has been presented for purposes of illustration and description, and is not intended to be exhaustive or limited to the examples described. Many alternatives and modifications may be used in place of the specific description set forth above.

For example, although this disclosure describes the widely adopted triple junction solar cell 100B, it could be broadened to cover any instance of a solar cell 100B comprising a single or multiple junction solar cell, e.g., single junction solar cells, double junction solar cells, or other multiple junction solar cells.

In another example, although the middle sub-cell 112B is described as comprising InGaAs and GaInAs, and the DBR 130 is described as comprising AlGaAs and GaAs, other materials could also be used.

In yet another example, although this disclosure describes the middle sub-cell 112B, base 114B, and DBR 130 are described as comprising certain materials, alternatives may describe the middle sub-cell 112B, base 114B, and DBR 130 as consisting of, or consisting essentially of, these or other materials.

In yet another example, this disclosure is applicable to inverted metamorphic (IMM) devices in any sub-cell to enhance the radiation retention of the devices. Specifically, this disclosure may be applied to GaAs, GaInAs, AlGaAs, AlGaInAs, GaInAsSb, GaInAsN, GaInAsNSb, GaInAsSb, GaAsSb, GaPAsSb sub-cells within that architecture.

In yet another example, reflectors other than DBRs 130 may be used to capture a second pass of light through the sub-cell 112B. Such reflectors may be embedded in the epitaxy, such as AlAs/GaAs, AlGaInAs/GaInAs, AlGaAsSb/GaAsSb and similar DBRs, or metal surfaces applied to the back of the sub-cell 112B, including low index materials, such as TiOx, SiOx, Al₂O₃ coated with a metal layer such as Ag, Au, Al, Ti, Pt, Ni, or similar common metals in semiconductor device fabrication.

Typically, the sub-cells have an n-on-p configuration as is usual for a p-type Ge substrate, which means that the emitter of the sub-cell is n-type and the base is p-type. However, other examples may comprise a p-on-n configuration, wherein the emitter of the sub-cell is p-type and the base is n-type.

Similarly, although this disclosure describes the new solar cell 100B performing in a desired manner at a radiation dose of about 1e15 e-/cm² to 1e16 e-/cm², alternatives may describe the new solar cell 100B as performing in the desired manner at radiation doses greater than or less than the range of about 1e15 e-/cm² to 1e16 e-/cm².

Aerospace Applications

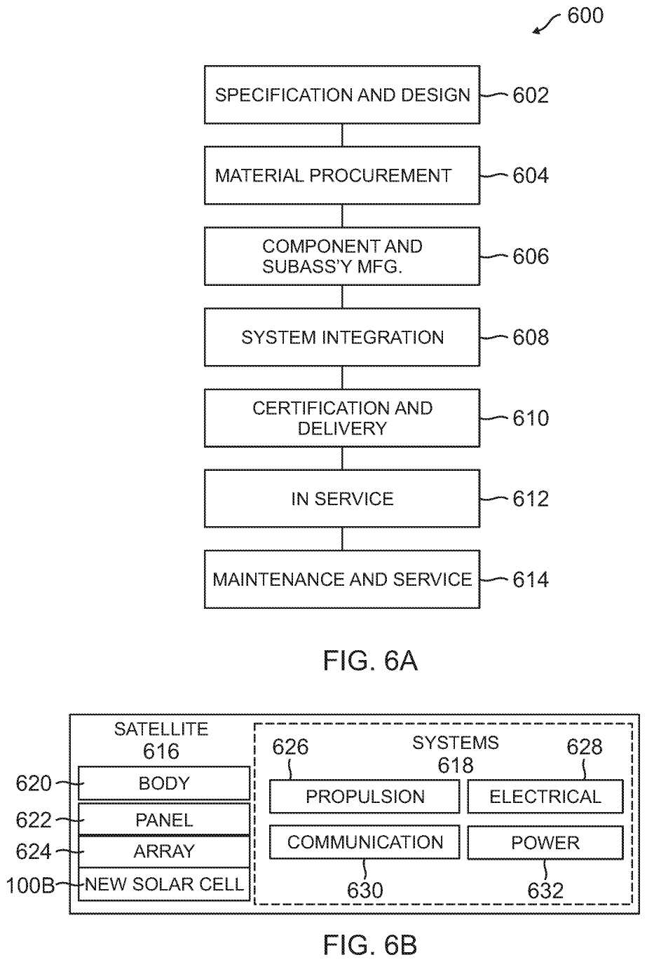

Examples of the disclosure may be described in the context of a method 600 of fabricating a solar cell, solar cell panel and/or aerospace vehicle such as a satellite, comprising steps 602-614, as shown in FIG. 6A, wherein the resulting satellite 616 comprised of various systems 618 and a body 620, including a panel 622 comprised of an array 624 of one or more new solar cells 100B is shown in FIG. 6B.

As illustrated in FIG. 6A, during pre-production, exemplary method 600 may include specification and design 602 of the satellite 616, and material procurement 604 for same. During production, component and subassembly manufacturing 606 and system integration 608 of the satellite 616 takes place, which include fabricating the satellite 616, panel 622, array 624 and new solar cells 100B. Thereafter, the satellite 616 may go through certification and delivery 610 in order to be placed in service 612. The satellite 616 may also be scheduled for maintenance and service 614 (which includes modification, reconfiguration, refurbishment, and so on), before being launched.

Each of the processes of method 600 may be performed or carried out by a system integrator, a third party, and/or an operator (e.g., a customer). For the purposes of this description, a system integrator may include without limitation any number of manufacturers and major-system subcontractors; a third party may include without limitation any number of venders, subcontractors, and suppliers; and an operator may be a satellite company, military entity, service organization, and so on.

As shown in FIG. 6B, the satellite 616 fabricated by exemplary method 600 may include various systems 618 and a body 620. Examples of the systems 618 included with the satellite 616 include, but are not limited to, one or more of a propulsion system 626, an electrical system 628, a communications system 630, and a power system 632. Any number of other systems also may be included.

Functional Block Diagram

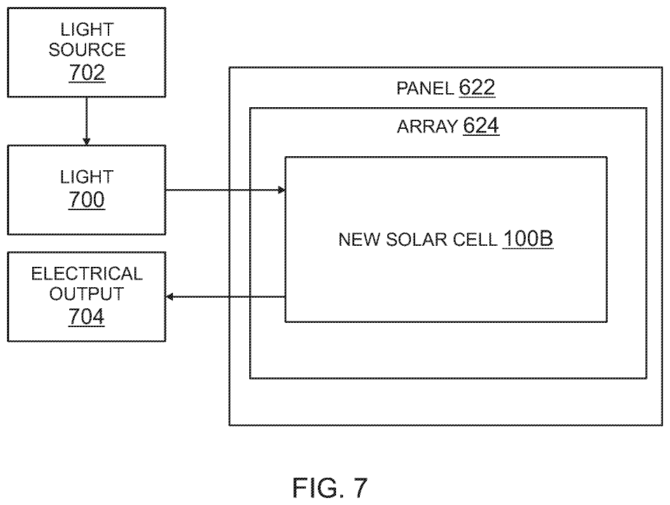

FIG. 7 is an illustration of the panel 622 in the form of a functional block diagram, according to one example. The panel 622 is comprised of the array 624, which is comprised of one or more of the new solar cells 100B individually attached to the panel 622. The solar cell 100B may comprise a single or multiple junction solar cell 100B, e.g., a single junction solar cell 100B, double junction solar cell 100B, or other multiple junction solar cell 100B. At least one of the new solar cells 100B includes a sub-cell 112B comprised of a base 114B and an emitter 116, the base 114B has a thickness of about 2 to 3 μm, the base 114B is p-type doped at about 1e14 cm⁻³ to 1e16 cm⁻³, and a DBR 130 is inserted behind the sub-cell 112B to maximize current generated by the sub-cell 112B. Each of the new solar cells 100B absorbs light 700 from a light source 702 and generates an electrical output 704 in response thereto.

What is claimed is:

1. A device, comprising:
a solar cell optimized for performance at high radiation doses, wherein the solar cell includes:
a sub-cell comprised of a base and an emitter;
the base of the sub-cell has a thickness of about 2 to 3 μm;
the base of the sub-cell is doped at about 1e14 cm⁻³ to 1e16 cm⁻³; and
a reflector is inserted behind the sub-cell to maximize current generated by the sub-cell.

2. The device of claim 1, wherein the high radiation doses comprise radiation doses of about 1e15 e-/cm² to 1e16 e-/cm².

3. The device of claim 1, wherein the solar cell is a single junction or multiple junction solar cell.

4. The device of claim 1, wherein the reflector is a distributed Bragg reflector comprised of aluminum gallium arsenide (AlGaAs) and gallium arsenide (GaAs).

5. The device of claim 1, wherein the reflector is positioned between a buffer layer and a lower tunnel junction of the solar cell.

6. The device of claim 1, wherein the reflector has a reflectance centered at a wavelength of about 870 nm.

7. The device of claim 1, wherein the sub-cell is a middle sub-cell of the solar cell.

8. The device of claim 1, wherein the emitter of the sub-cell is comprised of indium gallium arsenide (InGaAs).

9. The device of claim 1, wherein the base of the sub-cell is comprised of gallium indium arsenide (GaInAs).

10. The device of claim 1, wherein the base of the sub-cell has a thickness of about 2.1 to 2.3 μm.

11. The device of claim 1, wherein the base of the sub-cell has a thickness of about 2.1 μm.

12. The device of claim 1, wherein the solar cell is optimized for performance at the high radiation doses as compared to a baseline solar cell having a thicker sub-cell base and no reflector.

13. The device of claim 12, wherein a power retention as a function of a 1 MeV electron radiation dose of the solar cell is similar to the baseline solar cell for the 1 MeV electron radiation dose from about 0 to 5e14 e-/cm².

14. The device of claim 12, wherein a power retention as a function of a 1 MeV electron radiation dose of the solar cell is greater than the baseline solar cell for the 1 MeV electron radiation dose from about 1e15 e-/cm² to 1e16 e-/cm².

15. The device of claim 12, wherein the beginning-of-life (BOL) efficiency of the solar cell is greater than the baseline solar cell at all radiation doses.

16. The device of claim 12, wherein an end-of-life (EOL) efficiency of the solar cell is greater than the baseline solar cell at all radiation doses.

17. The device of claim 1, further comprising a panel including the solar cell.

18. The device of claim 17, further comprising a space vehicle including the panel.

19. A method, comprising:
fabricating a solar cell optimized for performance at high radiation doses, wherein the solar cell includes:
a sub-cell comprised of a base and an emitter;
the base of the sub-cell has a thickness of about 2 to 3 μm;
the base of the sub-cell is doped at about 1e14 cm⁻³ to 1e16 cm⁻³; and
a reflector is inserted behind the sub-cell to maximize current generated by the sub-cell.

20. A method, comprising:
generating a current using a solar cell optimized for performance at high radiation doses, wherein the solar cell includes:
a sub-cell comprised of a base and an emitter;
the base of the sub-cell has a thickness of about 2 to 3 μm;
the base of the sub-cell is doped at about 1e14 cm⁻³ to 1e16 cm⁻³; and
a reflector is inserted behind the sub-cell to maximize current generated by the sub-cell.
